(19) United States
(12) Patent Application Publication
(10) Pub. No.: US 2026/0305085 A1
(43) Pub. Date: Oct. 1, 2026

(54) DISPLAY APPARATUS

(71) Applicant: LG Display Co., Ltd., Seoul (KR)

(72) Inventors: Kyeong-Yeon PARK, Paju-si (KR); Myeong-Su KIM, Paju-si (KR)

(73) Assignee: LG Display Co., Ltd., Seoul (KR)

(21) Appl. No.: 19/454,989

(22) Filed: Jan. 21, 2026

(30) Foreign Application Priority Data
Mar. 31, 2025 (KR) 10-2025-0041555

(51) Int. Cl. H10K 59/124; H10K 59/131; H10K 59/88

(52) U.S. Cl. CPC H10K 59/124; H10K 59/131; H10K 59/88

(57) ABSTRACT

A display apparatus includes a substrate having a display area with a plurality of sub-pixels that include a thin film transistor and a light emitting device, and a non-display area having a dummy area with a plurality of dummy sub-pixels. A hydrogen collection member is disposed in the non-display area to collect hydrogen from outside, and a voltage is applied to the hydrogen collection member to enhance hydrogen collection. The arrangement reduces hydrogen penetration toward the thin film transistor and supports stable electrical characteristics across the display area.

### CROSS-REFERENCE TO RELATED APPLICATIONS

This application claims priority to Korean Patent Application No. 10-2025-0041555, filed in the Republic of Korea on Mar. 31, 2025, the entire contents of which is hereby expressly incorporated by reference into the present application.

### BACKGROUND

### Technical Field

The present disclosure relates to a display apparatus capable of removing hydrogen penetrating from the outside.

### Description of the Related Art

Recently, with the development of multimedia, the importance of display apparatuses is increasing. In response to this, flat panel display apparatuses, such as a liquid crystal display apparatus, a plasma display apparatus, and an organic light emitting display apparatus, are being commercialized. Among these display apparatuses, the organic light emitting display apparatus is currently widely used because of its high response speed, high luminance, and wide viewing angle.

Organic light emitting device is very vulnerable to foreign substances such as moisture and oxygen. In particular, in the case of the display apparatus including an oxide semiconductor transistor, when the hydrogen generated during the manufacturing process penetrates into the oxide semiconductor layer, a specific area of the oxide semiconductor layer becomes a conductor, and such conduction has a problem of causing abnormal light emission of the light emitting device by changing the threshold voltage of the transistor.

### BRIEF SUMMARY

The present disclosure introduces an active hydrogen collection architecture for oxide semiconductor display panels, addressing hydrogen driven threshold voltage instability in thin film transistors. Instead of relying only on passive encapsulation, the design places a hydrogen absorbing metal member, preferably titanium or a titanium alloy, in the non display perimeter where it surrounds the display area and intercepts externally penetrating hydrogen. A voltage, typically a negative voltage, is applied to this metal so that an electric field promotes hydrogen diffusion into the titanium lattice, which significantly increases the efficiency of hydrogen capture and protects the thin film transistors.

The structure is made suitable for narrow bezel displays through careful integration into the existing layer stack. The hydrogen collection member and the voltage applying member can share metallization layers with thin film transistor connection electrodes, or they may be vertically interconnected through stacked planarization layers and contact holes. This allows application of the collection voltage without requiring additional lateral space. The approach also supports configurations in which existing dummy pixel wiring, such as dummy gate lines and dummy data lines composed of titanium, are used as hydrogen collection elements, which reduces process steps and manufacturing cost while maintaining functional coverage around the display.

The structures described provide an arrangement that applies an electrical bias to a hydrogen absorbing material, locates that material strategically in non display regions, and incorporates it in a manner that is compatible with planarization structures and dummy line patterns. These features produce a robust and layout efficient method for suppressing hydrogen related degradation in oxide semiconductor thin film transistors across a wide range of panel designs.

Various embodiments of the present disclosure provide a display apparatus capable of preventing characteristic defects of the thin film transistor by collecting hydrogen penetrating from the outside to prevent threshold voltage transition of the thin film transistor by hydrogen.

A display apparatus according to the present disclosure comprises a substrate including a display area having a plurality of sub-pixels including a thin film transistor and a light emitting device and a non-display area having a dummy area including a plurality of dummy sub-pixels; and a hydrogen collection member disposed in the non-display area to collect hydrogen from outside, wherein a voltage is applied to the hydrogen collection member.

The hydrogen collection member may be made of titanium or a titanium-based alloy.

A voltage applying member is disposed in the non-display area to apply the voltage to the hydrogen collection member.

A first planarization layer is disposed over the thin film transistor and a first connection electrode is disposed on the first planarization layer to be connected electrically to the thin film transistor through a first contact hole formed in first planarization layer. Further, a second planarization layer is disposed on the first planarization layer on which the first connection electrode is disposed, and a second connection electrode is disposed on the second planarization layer to be electrically connected to the first connection electrode through a second contact hole formed in second planarization layer. A third planarization layer is disposed on the second planarization layer on which the second connection electrode is disposed.

The hydrogen collection member and the voltage applying member may be disposed on the same layer. At this time, the hydrogen collection member and the voltage applying member may be disposed on the second planarization layer, and the hydrogen collection member and the voltage applying member may be made of the same metal as the second connection electrode. A first connection member can connect electrically the hydrogen collection member to the voltage applying member.

The hydrogen collection member may be disposed on the second planarization layer and the voltage applying member may be disposed on the interlayer insulating layer. At this time, a second connection member is disposed on the first planarization layer, and the second connection member is connected to the voltage applying member through a third contact hole formed in the first planarization layer and is connected to the hydrogen collection member through a fourth contact hole formed in the second planarization layer

The voltage applying may be made of the same material as the source electrode and the drain electrode of the thin film transistor, the second connection member may be made of the same material as the first connection electrode, and the hydrogen collection member may be made of the same material as the second connection electrode.

A dummy gate line and a dummy data line are disposed in the dummy area to define the dummy sub-pixel. The dummy gate line and the dummy data line may be made of titanium or a titanium-based alloy, and the dummy gate line and the dummy data line disposed at the outermost side of the dummy area can act as hydrogen collection members.

### BRIEF DESCRIPTION OF THE SEVERAL VIEWS OF THE DRAWINGS

FIG. 1 is a schematic block diagram of a display apparatus according to the present disclosure.

FIG. 2 is the schematic block diagram of a sub pixel according to the present disclosure.

FIG. 3 is a circuit diagram conceptually illustrating the sub pixel of an organic light emitting display apparatus according to the present disclosure.

FIG. 4 is a plan view schematically illustrating a structure of the display apparatus according to the present disclosure.

FIG. 5 is an enlarged plan view of area A of FIG. 4.

FIG. 6 is a cross-sectional view taken along a line I-I′ of FIG. 5 illustrating the display apparatus according to a first embodiment of the present disclosure.

FIG. 7 is a cross-sectional view of the display apparatus according to a second embodiment of the present disclosure.

FIG. 8 is a partial plan view of a display apparatus according to a third embodiment of the present disclosure.

### DETAILED DESCRIPTION

Advantages and features of the present disclosure and methods for achieving them will be made clear from example embodiments described below in detail with reference to the accompanying drawings. The present disclosure may, however, be implemented in many different forms and should not be construed as being limited to the example embodiments set forth herein. The example embodiments are provided such that this disclosure will be more thorough and complete and will more fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure, unless otherwise specified. Further, in the following description of the present disclosure, where a detailed description of a known related art may unnecessarily obscure a feature or aspect of the present disclosure, the detailed description of such known related art may be omitted herein.

Where terms such as “including,” “having,” “comprising,” and the like are used in this disclosure, other parts may be added unless a more specific term like “only” is used herein. Where a component is expressed as being singular, being plural is included unless otherwise specified.

In analyzing a component, an error range is to be interpreted as being included even where there is no explicit description.

In a description of a positional relationship, for example, where a positional relationship of two parts is described as being “on,” “above,” “below,” “next to,” or the like, one or more other parts may be located between the two parts unless a more specific term like “immediately” or “directly” is used.

In a description of a temporal relationship, for example, where a temporal predecessor relationship is described as being “after,” “subsequent,” “next to,” “prior to,” or the like, cases that are not continuous or consecutive may also be included unless a more specific term like “immediately” or “directly” is used.

Although such terms as first, second, and the like may be used to describe various components, these components are not substantially limited by these terms. These terms are used only to refer to one component separately from another component. Therefore, a first component described below may substantially be a second component, and vice versa, within the technical spirit of the present disclosure.

In describing the components of the disclosure, terms such as first, second, A, B, (a), (b), etc., may be used. These terms are only for referring to the elements separately from other elements, and the essence, order, or number of the elements is not limited by the terms. Where a component is described as being “coupled” or “connected” to another component, the component may be directly or indirectly coupled or connected to the other component, unless a more specific term like “directly” is used. It should be understood that one or more other components may be “interposed” and connected between the components that are “coupled” or “connected” to each other.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner.

As used herein, the term “apparatus” may refer to a display apparatus such as a liquid crystal module (LCM) or an organic light emitting display module (OLED module) that includes a display panel and a driving unit (or a driving circuit) for driving the display panel. Further, the term “apparatus” may refer to a notebook computer, a television, a computer monitor, a vehicle electric apparatus including an apparatus for a vehicle or other type of vehicle, or a set electronic apparatus or a set apparatus, such as a mobile electronic apparatus of a smart phone, an electronic pad, or the like, which is a finished product (a complete product or a final product) including an LCM or an OLED module.

Accordingly, the apparatus in the present disclosure may encompass a display apparatus itself, such as the LCM, the OLED module, etc., and an apparatus for end users like an application product or a set apparatus that includes the LCM, the OLED module, or the like.

Hereinafter, various example embodiments of the present disclosure will be described in detail with reference to the accompanying drawings.

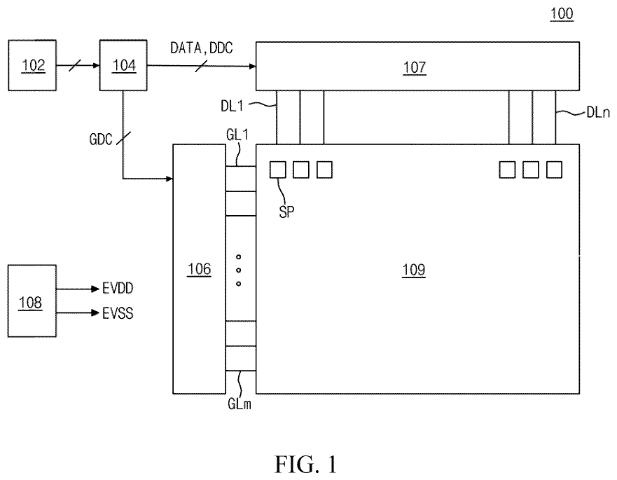

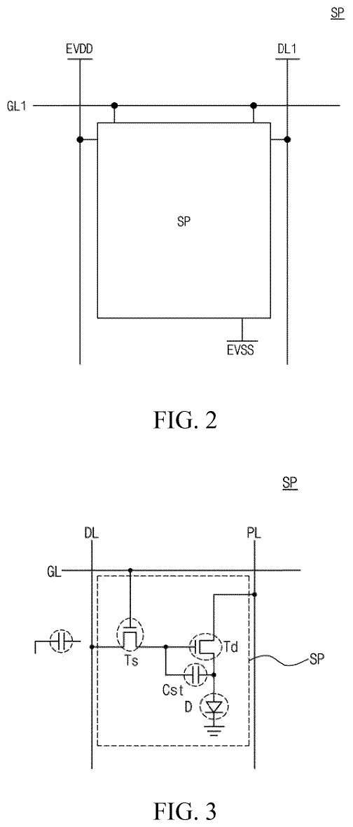

FIG. 1 is a schematic block diagram of a display apparatus according to one or more example embodiments of the present disclosure, and FIG. 2 is the schematic block diagram of a sub-pixel SP of an organic light emitting display apparatus according to one or more example embodiments of the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driving unit 106 includes various gate driving circuits, and the gate driving circuit can be formed directly on the substrate of the display panel 109. In this case, the gate driving unit 106 can be a GIP (Gate-In-Panel).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

Further, the power supply unit 108 may output and supply a hydrogen collection voltage to the display panel 109. As will be described in detail later, the hydrogen collection voltage is applied to the hydrogen collection metal disposed in the display panel 109 to collect hydrogen penetrating from the outside, thereby preventing hydrogen penetration into the display panel 109. The hydrogen collection voltage may be voltages of various intensities. For example, the hydrogen collection voltage may be a voltage having a negative (−) value, or may be a voltage having a positive (+) value capable of forming a negative electric field compared to a voltage applied to the peripheral wiring.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include composed of two transistors and one capacitor (2T1C), but is not limited thereto, and the sub-pixel SP may be composed of 3T1C, 4T1C, 5T1C, 6T1C, 7T1C, 3T2C, 4T2C, 5T2C, 6T2C, 7T2, 8T2C, etc.

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

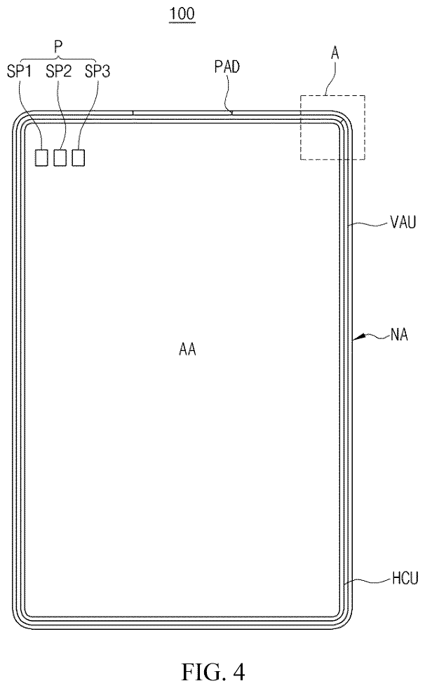

FIG. 4 is a plan view schematically showing the structure of the display apparatus 100 according to the present disclosure.

As shown in FIG. 4, the display apparatus 100 according to the present disclosure includes a display area AA where an actual image is displayed and a non-display area NA outside the display area AA.

A pixel P including a plurality of sub-pixels SP1, SP2, and SP3 is arranged in the display area AA. At this time, each of the sub-pixels SP1, SP2, and SP3 may include a red (R) sub-pixel, a green (G) sub-pixel, and a blue (B) sub-pixel. In addition, the pixel P may further include a white (W) sub-pixel.

Although not shown in the figure, a plurality of gate lines and data lines are arranged in the display area AA to define a plurality of sub-pixels SP in the intersection area of the gate lines and data lines. In each sub-pixel SP1, SP2, and SP3, a thin film transistor as a switching device and a display device for displaying an image are arranged.

The display device may include various display devices. For example, the display device may be an organic light emitting display device, a liquid crystal display device, a quantum dot display device, a micro LED display device, or a mini LED display device.

The gate driving unit and the data driving unit for supplying various signals to sub-pixels SP1, SP2, and SP3 can be disposed in the non-display area NA. The gate driving unit 106 applies the scan signal to the sub-pixels SP1, SP2, and SP3 through the gate line, and the data driving unit 107 applies the image signal to the sub-pixels SP1, SP2, and SP3 through the data line. In this case, the gate driving unit is a gate-in-panel including gate driving circuits.

Further, a hydrogen collection member HCU is disposed in the non-display area NA. The hydrogen collection member HCU collects hydrogen to block the penetration of hydrogen into the display apparatus 100.

The term “hydrogen collection member” refers to any structure formed on the substrate of the display apparatus and configured to attract, receive, absorb, capture, or otherwise remove hydrogen that penetrates toward the display area. The hydrogen collection member may include one or more conductive materials capable of interacting with hydrogen, such as titanium or a titanium based alloy, and may operate with or without an applied electrical potential. The hydrogen collection member may be arranged in any pattern or shape, may be formed in any metallization layer of the non display region, and may be implemented as a dedicated metal pattern or as part of an existing wiring structure including dummy wiring. Its function is to reduce or prevent hydrogen migration toward thin film transistors or other active elements of the display panel.

Various transistors may be disposed in the display apparatus 100. For example, a switching transistor and a driving transistor may be disposed in the sub-pixel SP of the display apparatus 100, and various transistors may be disposed in the GIP of the non-display area NA. In particular, in recent years, transistors with oxide semiconductors capable of low-temperature processes and having high mobility have been proposed. However, when the hydrogen is doped, the oxide semiconductor becomes conductor, and such conductor changes the threshold voltage of the oxide semiconductor, causing the transistor to deteriorate in characteristics.

In the present disclosure, the hydrogen is blocked to prevent the change of the threshold voltage due to oxidation of the oxide semiconductor. To this end, in the present disclosure, the hydrogen penetration into the transistor is prevented by forming the hydrogen collection member HCU with the metal capable of collecting hydrogen.

Various metals such as titanium (Ti) and molybdenum-titanium alloy (MoTi) may be used as the hydrogen collection metal. For example, titanium (Ti) has a face-centered cubic structure (FCC) and a body-centered cubic structure (BCC). In these structures, hydrogen atoms enter within the lattice or form hydrides. In particular, titanium forms a compound such as titanium hydrides (TiH₂), and since the compound stably exists in the titanium crystal structure, hydrogen may be effectively collected.

Since hydrogen penetrates through the entire area of the display apparatus 100, the hydrogen collection member HCU may be disposed in the non-display area NA along the entire circumference of the display area AA.

In particular, in the present disclosure, by applying a collection voltage of a predetermined value to the hydrogen collection member HCU to improve hydrogen collection efficiency, so that the transition of the threshold voltage of the transistor by the hydrogen penetration may be effectively prevented The collection voltage may be a negative voltage (−V) less than 0V. For example, the collection voltage may be −5V.

When the collection voltage is applied to the hydrogen collection metal such as titanium, hydrogen ions (H+) are better diffused into the metal and the hydrogen collection rate increases significantly due to the electric field effect of titanium, so that hydrogen can be blocked more efficiently from the outside.

Further, a voltage applying member VAU may be disposed in the non-display area NA of the present disclosure. The voltage applying member VAU is electrically connected to the hydrogen collection member HCU to apply the collection voltage to the hydrogen collection member HCU, thereby improving the hydrogen collection capacity of the hydrogen collection member HCU.

The voltage applying member VAU may be formed at various regions in various shapes. For example, as shown in the drawing, the hydrogen collection member HCU and the voltage applying member VAU are formed in the non-display area NA along the entire circumference of the display area AA. In this case, the voltage applying member VAU may be disposed outside the hydrogen collection member HCU, or the voltage applying member VAU may be disposed outside the hydrogen collection member HCU. The voltage applying member VAU may be electrically connected to an external power supply unit through a pad PAD so that a hydrogen collection voltage from the power supply unit may be applied to the voltage applying member VAU.

Further, the voltage applying member VAU may be disposed only in some areas, not be disposed in the non-display area NA along the entire circumference of the display area AA.

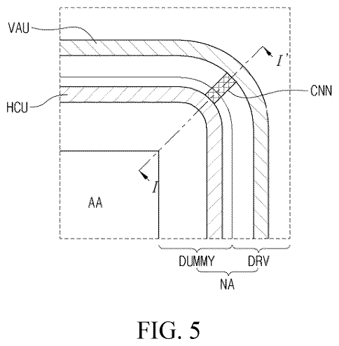

FIG. 5 is an enlarged plan view of area A of FIG. 4.

As shown in FIG. 5, the non-display area NA is disposed outside the display area AA, and the non-display area NA includes a dummy area DUMMY and a driving area DRV.

The dummy area DUMMY is the area in which the dummy sub-pixel is formed. The dummy sub-pixel is formed in the same structure as the sub-pixel of the display area, but the image is not displayed. For example, the dummy sub-pixel is defined by the gate line and the data line, and a plurality of layers, a plurality of film transistors, and light emitting device can be disposed in each dummy sub-pixel, as the dummy sub-pixel. However, the thin film transistor and the light emitting device in the dummy sub-pixel may not be driven because the driving signal is not applied.

Further, the thin film transistor and the light emitting device are not disposed in the dummy sub-pixel.

In the present disclosure, since the dummy area DUMMY is disposed between the display area AA and the driving area DRV, the structural difference between the display area AA and the driving area DRV may be mitigated, so that the problems caused by the rapid structural change may be solved. For example, the step between the display area AA and the driving area DRV is mitigated by the dummy area DUMMY, so that the various signal lines extending from the driving area DRV to the display area AA cannot be disconnected due to the step.

Further, when the organic layer is formed in the display area AA, some of the organic materials coated in the display area AA are also spread to the dummy area DUMMY, so that the organic layer may be uniformly coated in the display area AA.

The various driving devices may be disposed in the driving region DRV. For example, the data driving unit may be disposed in the driving region DRV. Further, the gate driving device may be disposed in a GIP format or a MUX may be disposed in the driving region DRV.

Further, the various signal lines may be disposed in the driving region DRV. For example, the power line for applying the low potential voltage and the high potential voltage, the gate link line for applying the gate signal, the signal line for applying a data enable signal, a vertical synchronization signal, a horizontal synchronization signal, a clock signal, and the like may be disposed in the driving region DRV.

The hydrogen collection member HCU may be disposed in the dummy area DUMMY. The hydrogen collection member HCU may be formed in a band shape having a small width to surround the entire display area AA. In this case, the hydrogen collection member HCU may be disposed on the upper end portion of the dummy area DUMMY, that is, in the dummy area DUMMY adjacent to the driving area DRV, but may also be disposed in the dummy area DUMMY adjacent to the display area AA.

The voltage applying member VAU is disposed in the driving area DRV. The voltage applying member VAU may be the gate link line and the signal line to which various signals such as a data enable signal, a vertical synchronization signal, a horizontal synchronization signal, and a clock signal are applied. Further, the voltage applying member VAU may be a separate metal pattern rather than the conventional signal line.

The width of the hydrogen collection member HCU and the voltage applying member VAU may vary depending on the size of the display apparatus 100, the width of the hydrogen collection member HCU, the voltage applying member VAU, and the like to prevent the delay of the signal transmission due to resistance.

A connection member CNN is disposed between the hydrogen collection member HCU and the voltage applying member VAU to electrically connect the hydrogen collection member HCU and the voltage applying member VAU, so that the collection voltage supplied to the voltage applying member VAU from the outside is applied to the hydrogen collection member HCU.

In the drawing, the connection member CNN is disposed at the upper edge portion of the display apparatus 100, but the position of the connection member CNN is not limited to a specific position, but may be disposed at various positions. Further, a plurality of connection members CNN may be provided and may be disposed at various positions.

Hereinafter, a structure of the display apparatus 100 according to an embodiment of the present disclosure will be described in more detail with reference to the accompanying drawings.

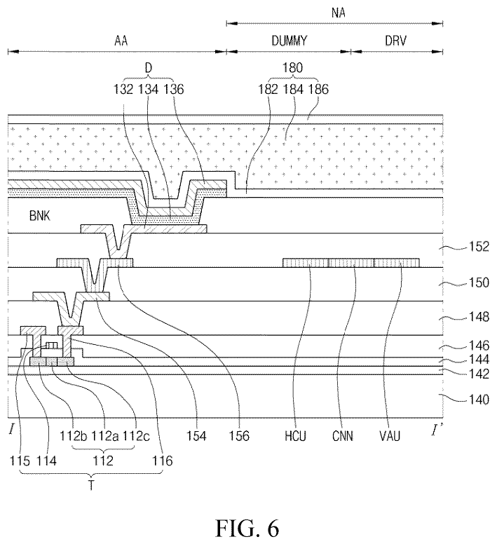

FIG. 6 is a cross-sectional view taken along a line I-I′ of FIG. 5, illustrating the display apparatus 100 according to a first embodiment of the present disclosure. In this case, for convenience of description, one sub-pixel SP in the display area AA, the hydrogen collection member HCU in the dummy area DUMMY, and the voltage applying member VAU in the driving area DRV are shown.

As shown in FIG. 6, the substrate 140 the display area AA, the dummy area DUMMY, and the non-display area NA in which the bending area BA is formed.

The substrate 140 may be made of a plastic material. For example, the plastic material may include a polyimide, a polymethylmethacrylate, a polyethylene tereththalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer in the display area AA. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

Further, the semiconductor pattern 112 may be made of a polycrystalline semiconductor. For example, the polycrystalline semiconductor may be made of low temperature poly silicon (LTPS) having high mobility, but is not limited thereto.

The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A first planarization layer 148 is formed on the substrate where the thin film transistor is disposed. The first planarization layer 148 may be formed of the organic material such as photoacrylic. But it is not limited thereto. The first planarization layer 148 may include a plurality of layers including the inorganic layer and the organic layer.

A first connection electrode 154 is disposed on the first planarization layer 148 to be electrically connected to the drain electrode 116 of the thin film transistor T through the contact hole formed in the first planarization layer 148. The first connection electrode may be made of the metal.

A second planarization layer 150 is formed on the first planarization layer 148 on which the first connection electrode 154 is disposed. The second planarization layer 150 may be formed of the organic material such as photo acrylic. But it is not limited thereto. The second planarization layer 150 may include a plurality of layers including the inorganic layer and the organic layer. Further, the second planarization layer 150 may be made of the same material as the first planarization layer 148, but may be made of a different material.

A second connection electrode 156 is disposed on the second planarization layer 150 to be electrically connected to the first connection electrode 154 through the contact hole formed in the second planarization layer 150. The second connection electrode 156 may be made of the metal.

The third planarization layer 152 is disposed on the second planarization layer 150 on which the second connection electrode 156 is disposed. The third planarization layer 152 may be made of the organic material such as photoacrylic, but is not limited thereto and may also be formed of a plurality of layers including the inorganic layer and the organic layer. The third planarization layer 152 may be made of the same material as those of the first planarization layer 148 and the second planarization layer 150, but may also be made of different materials.

As described above, in the present disclosure, since the planarization layer is formed in a plurality of structures 148, 150, and 152, various electrodes and signal lines may be disposed between the first to third planarization layers 148, 150, and 152. Therefore, since the electrodes may be vertically arranged, the area where the electrodes and signal lines are disposed in the sub-pixel may be reduced. As a result, the area of the sub-pixels is reduced, and thus the high-resolution display apparatus 100 may be manufactured.

A light emitting device D is disposed on the third planarization layer 152. The light emitting device D includes a first electrode 132, a light emitting layer 134, and a second electrode 136.

The first electrode 132 is disposed on the third planarization layer 152 and electrically connected to the second connection electrode 155 through the contact hole formed in the third planarization layer 152. That is, the first electrode 132 is electrically connected to the drain electrode 116 of the thin film transistor T through the first connection electrode 154 and the second connection electrode 156. The first electrode 132 may be formed of at least one of silver (Ag), aluminum (Al), gold (Au), molybdenum (Mo), tungsten (W), chromium (Cr), or an alloy thereof.

Further, the first electrode 132 may be formed of a transparent metal oxide material such as indium tin oxide (ITO) or indium zinc oxide (IZO). When the first electrode 132 is formed of the transparent metal oxide, the first electrode 132 may further include a reflective electrode made of a conductive material to reflect light.

A bank layer BNK is formed at the boundary between the sub-pixels on the third planarization layer 152. The bank layer BNK may be a barrier wall to define sub-pixels SP1 and SP2. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as Benzo Cyclo Butene, acrylic resin, epoxy resin, phenolic resin, polyamide resin, or the photosensitizer including black pigment, but is not limited thereto.

Further, the bank layer BNK may include a light absorbing material or a light blocking material. For example, the bank layer BNK may be formed of at least one material that absorbs light of a specific wavelength. The bank layer BNK may have the structure in which at least two layers of a red color filter, a green color filter, and a blue color filter are stacked.

The light emitting layer 134 may be formed in the R, G, and B pixels and may include an R-emitting layer that emits red light, a G-emitting layer that emits green light, and a B-emitting layer that emits blue light. For example, The light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 may be formed of a transparent conductive material that transmits light and may be disposed on the light emitting layer 134. For example, the second electrode 136 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag. Further, the second electrode 136 may be formed of a transparent metal oxide such as indium tin oxide (ITO) or indium zinc oxide (IZO), but is not limited thereto.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 180 is formed over the light emitting device D to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D oxidizes the metal electrode. The encapsulation layer 180 blocks impurities such as oxygen and moisture from the outside to prevent defects of the light emitting device D and various electrodes.

The encapsulation layer 180 may include a first encapsulation layer 182, a second encapsulation layer 184, and a third encapsulation layer 186, but is not limited thereto. The encapsulation layer 180 may be formed of two layers or four or more layers.

The first encapsulation layer 182 and the third encapsulation layer 186 may be formed of the inorganic material such as SiOx, SiON, SiNx, or the like, and may further include the organic material between inorganic materials such as SiOx, SiON, or SiNx, but are not limited thereto. The second encapsulation layer 184 may be formed of the organic insulating material such as epoxy resin.

Although not shown in figure, a touch member may be disposed on the encapsulating layer 180. The touch member can detect external touch information using the user's finger or a touch pen.

The hydrogen collection member HCU is disposed on the third planarization layer 152 in the dummy region DUMMY. The hydrogen collection member HCA may be made of a hydrogen collection metal such as titanium (Ti) or molybdenum-titanium alloy (MoTi). The hydrogen collection member HCU may be formed of the same material by the same process as the second connection electrode 156, but is not limited thereto.

The voltage applying member VAU is disposed in the driving area DRV. Although not shown in the drawings, the voltage applying member VAU is electrically connected to the external power supply unit so that the collection voltage is applied from the power supply unit to the voltage applying member VAU. The voltage applying member VAU may be made of the same metal as the hydrogen collection member HCA, but is not limited thereto.

The connection member CNN is disposed between the dummy area DUMMY and the driving area DRV. The connection member CNN electrically connects the hydrogen collection member HCA and the voltage applying member VAU to apply the collection voltage supplied to the voltage applying member VAU from the outside to the hydrogen collection member HCA so that hydrogen penetrating from the outside is collected by the hydrogen collection member HCA.

The connection member CNN may be made of the same metal as the hydrogen collection member HCA and/or the voltage applying member VAU, but is not limited to it.

As described above, in the display apparatus 100 according to the present disclosure, the hydrogen collection member HCA is provided and a negative collection voltage is applied to prevent the penetration of the hydrogen into the display area from the outside, so that defects such as threshold voltage transitions of the thin film transistor may be prevented.

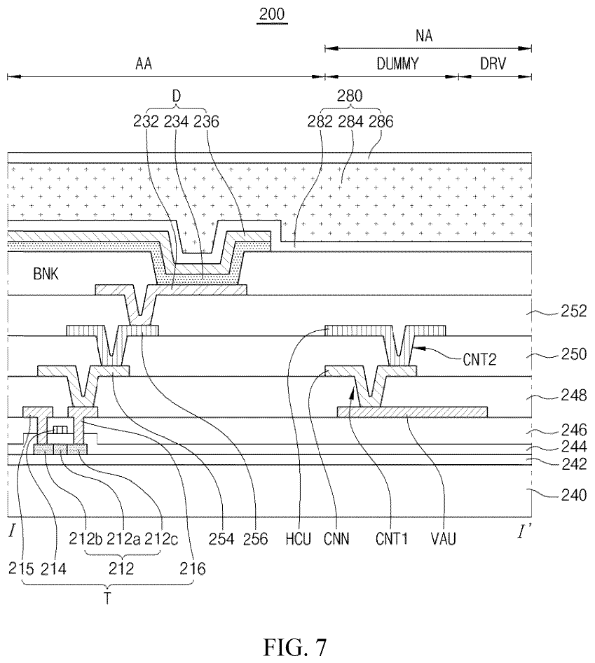

FIG. 7 is a cross-sectional view of the display apparatus 200 according to a second embodiment of the present disclosure. In this case, only the structure different from that of the display apparatus 100 according to the first embodiment of FIG. 6 will be described in detail, and the same structure will be omitted or briefly described.

As shown in FIG. 7, the thin film transistor T is disposed in the display area AA. First to third planarization layers 248, 250, and 252 are disposed over the thin film transistor T. The first to third planarization layers 248, 250, and 252 may be formed of the organic material, but are not limited thereto.

The source electrode 215 and the drain electrode 216 of the thin film transistor T are disposed on the interlayer insulating layer 246 of the display area AA, and the voltage applying member VAU is disposed in the driving area DRV. The voltage applying member VAU may be made of the same metal as the source electrode 215 and the drain electrode 216, but may be formed of another metal. In this case, the voltage applying member VAU extends from the driving area DRV to the dummy area DUMMY.

The first connection electrode 254 is disposed on the first planarization layer 248 of the display area AA and is electrically connected to the drain electrode 216 of the thin film transistor T through the contact hole formed in the first planarization layer 248. Further, the connection member CNN is disposed on the first planarization layer 248 of the dummy area DUMMY and is electrically connected to the voltage applying member VAU through a first contact hole CNT1 formed in the first planarization layer 248.

The second connection electrode 256 is disposed on the second planarization layer 250 of the display area AA and is electrically connected to the first connection electrode 254 through the contact hole formed in the second planarization layer 250. Further, the hydrogen collection member HCA is disposed on the second planarization layer 250 of the dummy area DUMMY. The hydrogen collection member HCA may be formed of the metal having the face-centered cubic structure (FCC) or the body-centered cubic structure (BCC), such as titanium (Ti) or molybdenum-titanium alloy (MoTi). The hydrogen collection member HCA is electrically connected to the connection member CNN through a second contact hole CNT2 formed in the second planarization layer 250.

In other words, since the hydrogen collection member HCA is electrically connected to the voltage applying member VAU through the connection member CNN, the collection voltage of negative value supplied from the outside is applied to the hydrogen collection member HCA to block the transfer of hydrogen to the display area AA from the outside.

As described above, in the display device 200 of this embodiment, since the hydrogen collection member HCA and the voltage applying member VAU are electrically connected through the first and second contact holes CNT1 and CNT2, a connection area of the hydrogen collection member HCA and the voltage applying member VAU may be minimized. Therefore, a bezel area of the display device 200 may be minimized.

Meanwhile, the voltage applied to the hydrogen collection member HCA may be applied in various forms. A separate hydrogen collection voltage may be directly applied to the hydrogen collection member HCA from the external power supply unit. In this case, the voltage may be various signals applied to a display apparatus such as the low potential voltage, the gate signal, the data enable signal, the vertical synchronization signal, the horizontal synchronization signal, and a clock signal.

In the display apparatus in accordance with the first and second embodiments, the hydrogen collection member HCA is formed in the dummy area and the voltage applying member VAU is disposed in the driving area, but this disclosure is not limited to this structure. For example, when the dummy area is not formed in the display apparatus and only the non-display area including the driving area is formed in the display apparatus, the hydrogen collection member HCA and the voltage applying member VAU may be formed in the non-display area. Further, even when the dummy area is formed in the display apparatus, the hydrogen collection member HCA and the voltage applying member VAU may be formed in the non-display area, not in the dummy area.

In other words, since the hydrogen collection member HCA of the present disclosure is for blocking (collecting) hydrogen penetrating into the display area, the hydrogen collection member HCA may be disposed at various positions as long as the hydrogen collection member HCA can be formed outside the display area.

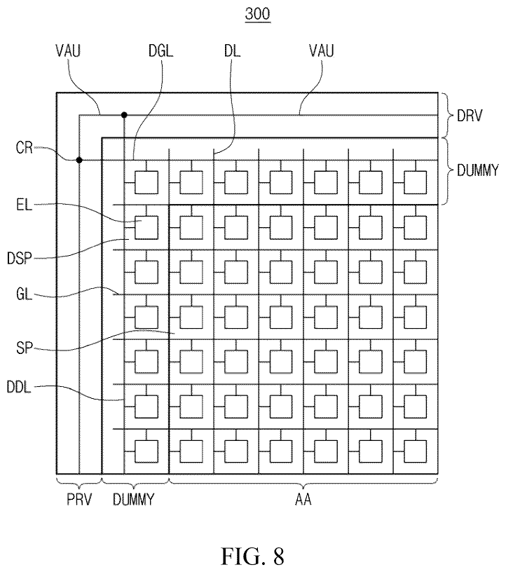

FIG. 8 is a partial plan view illustrating a display apparatus 300 according to a third embodiment of the present disclosure.

As shown in FIG. 8, the display apparatus 300 of this embodiment includes the display area AA, the dummy area DUMMY, and the driving area DRV.

The display area AA includes a plurality of sub-pixels to display the image. The dummy area DUMMY is disposed between the display area AA and the driving area DRV and includes a plurality of dummy sub-pixels DSP. Various driving devices and various signal lines are disposed in the driving area DRV.

A plurality of gate lines GL and data lines DL are disposed in the display area AA to define a plurality of sub-pixels SP. The thin film transistor (not shown) and the light emitting device EL are disposed in each of the sub-pixels SP.

The gate line GL and the data line DL of the display area AA extend to the dummy area DUMMY and the driving area DRV, and the dummy gate line DGL and the dummy data line DDL are disposed at the outermost side of the dummy area DUMMY.

The scan signal and the image signal are applied to the gate line GL and the data line DL, respectively, to drive the thin film transistor and the light emitting device EL disposed in the sub-pixel SP.

The thin film transistor and the light emitting device EL may also be disposed in the dummy sub-pixel DSP in the dummy region DUMMY. Since the scan signal and the image signal are not applied to the dummy gate line DGL and the dummy data line DDL, the thin film transistor and the light emitting device of the dummy sub-pixel DSP are not driven. Accordingly, the image is not displayed on the dummy sub-pixel DSP in the dummy region DUMMY. Further, the scan signals and the image signals are applied to the dummy gate line DGL and the dummy data line DDL, but the thin film transistor is not disposed in the dummy sub-pixel DSP, so the image may not be displayed in the dummy sub-pixel DSP in the dummy area DUMMY.

The voltage applying member VAU is disposed in the driving area DRV. The voltage applying member VAU is connected to the external power supply unit so that the hydrogen collection voltage is applied to the voltage applying member VAU from the power supply unit.

The voltage applying member VAU is electrically connected to the dummy gate line DGL and the dummy data line DDL in the connection area CR to apply the hydrogen collection voltage to the dummy gate line DGL and the dummy data line DDL, respectively. Since the dummy gate line DGL and the dummy data line DDL are made of hydrogen collection metal such as titanium (Ti) or molybdenum-titanium alloy (MoTi) and are arranged along the outer circumference of the display area AA, the dummy gate line DGL and the dummy data line DDL act as the hydrogen collection members when the hydrogen collection voltage is applied to the dummy gate line DGL and the dummy data line DDL.

The voltage applying member VAU may be disposed on the same layer as or on a different layer from the dummy gate line DGL or the dummy data line DDL. When the voltage applying member VAU is formed on the same layer as one of the dummy gate line DGL and the dummy data line DDL, the voltage applying member VAU is connected to the corresponding line of the dummy gate line DGL and the dummy data line DDL through a connection member (not shown). When the voltage applying member VAU is formed on a layer different from one of the dummy gate line DGL and the dummy data line DDL, the voltage applying member VAU may be connected to the corresponding line of the dummy gate line DGL and the dummy data line DDL through the contact hole (not shown).

As described above, in this embodiment, it is possible to prevent the threshold transition defect of the thin film transistor due to hydrogen by using the dummy gate line DGL or dummy data line DDL as the hydrogen collection member to collect hydrogen from the outside.

Therefore, since a separate hydrogen collection member is not required, the manufacturing process can be shortened and the manufacturing cost can be reduced.

Further embodiments of the present disclosure are detailed below.

In some embodiments, a display apparatus may include a substrate on which a display area AA and a non display area NA are defined in a plan view (see FIG. 4). The non display area may include a dummy area DUMMY that is disposed along an outer side of the display area, and a driving area DRV that is disposed outside the dummy area. The display apparatus may further include a hydrogen collection member HCU extending along the dummy area in the plan view (see FIG. 5). A voltage applying member VAU may extend along the driving area in the plan view and may be electrically connected to the hydrogen collection member. In this arrangement, the hydrogen collection member is positioned between the display area and the voltage applying member in the plan view so that hydrogen approaching the display area encounters the hydrogen collection member before reaching thin film transistors or other active components in the display area.

In some embodiments, a voltage applied to the voltage applying member may be supplied directly to the hydrogen collection member. By applying this voltage to the hydrogen collection member, the hydrogen collection member may collect hydrogen penetrating toward the display area. The applied voltage may create an electric field or potential difference that enhances the ability of the hydrogen collection member to attract or absorb hydrogen as it migrates from outside the display apparatus toward the display area.

In some embodiments, a voltage applied to the voltage applying member is supplied to the hydrogen collection member such that the hydrogen collection member is biased during operation of the display apparatus. The voltage applied to the hydrogen collection member through the voltage applying member may have a negative value relative to a voltage applied to wiring in the display area. By maintaining the hydrogen collection member at a negative potential relative to the display area wiring, hydrogen ions or hydrogen-containing species may be driven toward the hydrogen collection member, thereby further improving hydrogen collection efficiency.

In further embodiments, the hydrogen collection member may extend continuously along at least two sides of the display area in the plan view (see FIG. 4). For example, the hydrogen collection member may be formed as an elongate metal pattern or series of metal patterns arranged to run along two or more edges of the display area so that hydrogen approaching from multiple directions can be intercepted.

In some configurations, the hydrogen collection member and the voltage applying member may be disposed on a same planarization layer in the non display area (see FIG. 6). Locating both elements on the same planarization layer may simplify fabrication, allow for more efficient routing of the voltage from the voltage applying member to the hydrogen collection member, and permit layout optimization in regions outside the display area.

The display apparatus may further include a connection member that is disposed between the hydrogen collection member and the voltage applying member in the plan view. The connection member may be arranged to extend across a boundary between the dummy area and the driving area. By extending across this boundary, the connection member may provide an electrical pathway that links the hydrogen collection member located in the dummy area with the voltage applying member located in the driving area.

In some embodiments, the connection member may be arranged to overlap a plurality of signal lines disposed in the driving area without extending into the display area in the plan view. Such signal lines may include gate link lines, data lines, clock lines, or other control or power lines. The overlap may occur in regions of the non display area where metal wiring is already present, and the connection member may be routed to avoid interference with the display area while maintaining the required electrical connection.

In further embodiments, the connection member may be disposed on a same planarization layer as the hydrogen collection member (see FIG. 6). When arranged in this manner, the connection member may electrically connect the hydrogen collection member to the voltage applying member, either directly or through an additional interlayer connection. Placing the connection member and hydrogen collection member on the same planarization layer may improve routing efficiency and reduce the number of contact holes needed.

In some embodiments, the voltage applying member may be electrically coupled to the hydrogen collection member through a plurality of contact holes extending through different planarization layers in the non display area (see FIG. 7). These contact holes may permit electrical communication between metal layers located at different heights within the device structure, thereby enabling the voltage to be delivered from the voltage applying member to the hydrogen collection member even when they are formed in different metallization layers.

In another embodiment, the connection member may be disposed on a planarization layer and may be electrically connected to the voltage applying member through a first contact hole CNT1 and to the hydrogen collection member through a second contact hole CNT2. The first and second contact holes may extend through one or more insulating layers to reach the respective metal features, thereby enabling the connection member to bridge between the voltage applying member and the hydrogen collection member within the non display area.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area having a plurality of sub-pixels including a thin film transistor and a light emitting device and a non-display area having a dummy area including a plurality of dummy sub-pixels; and
a hydrogen collection member disposed in the non-display area, the hydrogen collection member configured to collect hydrogen,
wherein a voltage is applied to the hydrogen collection member.

2. The display apparatus of claim 1, wherein the hydrogen collection member is made of titanium or a titanium-based alloy.

3. The display apparatus of claim 1, wherein the voltage has negative value.

4. The display apparatus of claim 1, further comprising a voltage applying member disposed in the non-display area to apply the voltage to the hydrogen collection member.

5. The display apparatus of claim 4, further comprising:
a first planarization layer over the thin film transistor;
a first connection electrode on the first planarization layer, the first connection electrode being electrically connected to the thin film transistor through a first contact hole formed in the first planarization layer;
a second planarization layer on the first planarization layer on which the first connection electrode is disposed;
a second connection electrode on the second planarization layer, the second connection electrode being electrically connected to the first connection electrode through a second contact hole formed in second planarization layer; and
a third planarization layer on the second planarization layer on which the second connection electrode is disposed, a light emitting layer of the light emitting device being disposed on the third planarization layer.

6. The display apparatus of claim 5, wherein the hydrogen collection member and the voltage applying member are disposed on a same layer.

7. The display apparatus of claim 6, wherein the hydrogen collection member and the voltage applying member are disposed on the second planarization layer.

8. The display apparatus of claim 7, wherein the hydrogen collection member and the voltage applying member are made of a same metal as the second connection electrode.

9. The display apparatus of claim 7, further comprising a first connection member for connecting electrically the hydrogen collection member to the voltage applying member.

10. The display apparatus of claim 5, wherein the hydrogen collection member is disposed on the second planarization layer, and the voltage applying member is disposed on the interlayer insulating layer on which a source electrode and a drain electrodes of the thin film transistor are disposed.

11. The display apparatus of claim 10, further comprising a second connection member on the first planarization layer,
wherein the second connection member is connected to the voltage applying member through a third contact hole formed in the first planarization layer, and is connected to the hydrogen collection member through a fourth contact hole formed in the second planarization layer.

12. The display apparatus of claim 11, wherein the voltage applying member is made of the same material as the source electrode and the drain electrode of the thin film transistor, the second connection member is made of the same material as the first connection electrode, and the hydrogen collection member is made of the same material as the second connection electrode.

13. The display apparatus of claim 4, further comprising a dummy gate line and a dummy data line disposed in the dummy area to define the dummy sub-pixel.

14. The display apparatus of claim 13, wherein the dummy gate line and the dummy data line are made of titanium or a titanium-based alloy.

15. The display apparatus of claim 14, wherein the dummy gate line and the dummy data line disposed at an outermost side of the dummy area are hydrogen collection members.

16. The display apparatus of claim 13, wherein the voltage is not applied to the dummy gate line and the dummy data line.

17. A display apparatus comprising:
a substrate on which a display area and a non display area are defined in a plan view, the non display area including a dummy area disposed along an outer side of the display area and a driving area disposed outside the dummy area;
a hydrogen collection member extending along the dummy area in the plan view; and
a voltage applying member extending along the driving area in the plan view and electrically connected to the hydrogen collection member,
wherein the hydrogen collection member is arranged between the display area and the voltage applying member in the plan view.

18. The display apparatus of claim 17, wherein a voltage applied to the voltage applying member is supplied to the hydrogen collection member to collect hydrogen penetrating toward the display area.

19. The display apparatus of claim 17, wherein a voltage applied to the voltage applying member is supplied to the hydrogen collection member, and
wherein the voltage applied to the hydrogen collection member through the voltage applying member has a negative value relative to a voltage applied to wiring in the display area.

20. The display apparatus of claim 17, wherein the hydrogen collection member extends continuously along at least two sides of the display area in the plan view.
